(19) United States
(12) Patent Application Publication
(10) Pub. No.: US 2015/0280461 A1
(43) Pub. Date: Oct. 1, 2015

(54) ADJUSTING CHARGE VOLTAGE ON CELLS IN MULTI-CELL BATTERY

(71) Applicant: International Business Machines Corporation, Armonk, NY (US)

(72) Inventors: Yakup Bulur, Rochester, MN (US); Richard J. Fishbune, Rochester, MN (US); Mark E. Maresh, Cave Creek, AZ (US); Neil C. Swenson, Rochester, MN (US); Adam M. Wheeler, Rochester, MN (US)

(73) Assignee: International Business Machines Corporation, Armonk, NY (US)

(21) Appl. No.: 14/225,853

(22) Filed: Mar. 26, 2014

(51) Int. Cl. H02J 7/00; G01R 31/36

(52) U.S. Cl. CPC H02J 7/0013; G01R 31/3606; G01R 31/3648; G01R 31/3658; H02J 7/0047; H02J 7/0052; H02J 7/007; H02J 2007/005

(57) ABSTRACT

A method for charging a battery pack containing a plurality of cells is disclosed. The method includes receiving capacity information for a voltage adjustable set of the plurality of cells from two or more fuel gauges. Each of the two or more fuel gauges is associated with one cell in the adjustable set. The method further includes identifying a target cell for increasing charge voltage based on the capacity information. The method further includes sending a signal to a charge voltage controller associated with the target cell. The signal is configured to cause the charge voltage controller to increase charge voltage on the target cell. The charge voltage controller is one of a plurality of charge voltage controllers. Each of the plurality of charge voltage controllers is associated with one or more cells in the voltage adjustable set.

### BACKGROUND

The present disclosure relates to multi-cell battery packs, and more specifically, to charging of multi-cell battery packs.

When individual cells in a multi-cell battery start to lose capacity, the overall capacity of the battery is decreased. At some point the battery will no longer function as designed due to decreased capacity. Increasing the charging voltage on a battery can result in a higher capacity; however, it can reduce the life of the battery.

### SUMMARY

According to embodiments of the present disclosure, a method for charging a battery pack containing a plurality of cells is disclosed. The method includes receiving capacity information for a voltage adjustable set of the plurality of cells from two or more fuel gauges. Each of the two or more fuel gauges is associated with one cell in the adjustable set. The method further includes identifying a target cell for increasing charge voltage based on the capacity information. The method further includes sending a signal to a charge voltage controller associated with the target cell. The signal is configured to cause the charge voltage controller to increase charge voltage on the target cell. The charge voltage controller is one of a plurality of charge voltage controllers. Each of the plurality of charge voltage controllers is associated with one or more cells in the voltage adjustable set.

Also disclosed herein are embodiments of a computer program product for charging a battery pack containing a plurality of cells. The computer program product includes a computer readable storage medium having program code embodied therewith. The program code is executable by a computer to perform a method. The method includes receiving capacity information for a voltage adjustable set of the plurality of cells from two or more fuel gauges. Each of the two or more fuel gauges is associated with one cell in the adjustable set. The method further includes identifying a target cell for increasing charge voltage based on the capacity information. The method further includes sending a signal to a charge voltage controller associated with the target cell. The signal is configured to cause the charge voltage controller to increase charge voltage on the target cell. The charge voltage controller is one of a plurality of charge voltage controllers. Each of the plurality of charge voltage controllers is associated with one or more cells in the voltage adjustable set.

Also disclosed herein are embodiments of a computer system for charging a battery pack containing a plurality of cells. The computer system includes one or more processors, one or more computer-readable memories, one or more computer-readable tangible storage devices, and program instructions stored on at least one of the one or more storage devices for execution by at least one of the one or more processors via at least one of the one or more memories. The program instructions for execution include program instructions to receive capacity information for a voltage adjustable set of the plurality of cells from two or more fuel gauges. Each of the two or more fuel gauges is associated with one cell in the adjustable set. The program instructions for execution further include program instructions to identify a target cell for increasing charge voltage based on the capacity information. The program instructions for execution further include program instructions to send a signal to a charge voltage controller associated with the target cell. The signal is configured to cause the charge voltage controller to increase charge voltage on the target cell. The charge voltage controller is one of a plurality of charge voltage controllers. Each of the plurality of charge voltage controllers is associated with one or more cells in the voltage adjustable set.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a block diagram of an example battery pack for adjusting the charge voltage on individual cells.

FIG. 2 depicts a flow diagram of an example method for charging a multi-cell battery.

FIG. 3 depicts a flow diagram of an example method for charging a multi-cell battery.

FIG. 4 depicts a high-level block diagram of an example system for implementing one or more embodiments of the invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to charging multi-cell battery packs, more particular aspects relate to charging multi-cell battery packs by increasing the charging voltage on individual cells. While the present disclosure is not necessarily limited to such applications, various aspects of the disclosure may be appreciated through a discussion of various examples using this context.

Present technology may not allow for recovery of capacity that has been lost in a multi-cell battery due to individual cell capacity loss. Embodiments of the present invention may allow for increasing charge voltage on an individual cell. This may allow for increasing the capacity on an individual cell to increase the overall capacity of the battery. Because increasing the charge voltage on an individual cell can result in a shorter life for the cell, the charge voltage may be increased only when the overall battery capacity is so low that it does not function correctly.

Embodiments of the present invention may provide a multi-cell battery pack with a fuel gauge and a charge voltage controller associated with each cell in the battery. Each fuel gauge may communicate the capacity of the associated cell to a master controller. The master controller may determine an overall capacity for the battery based on the capacities of the individual cells. The master controller may determine that the overall capacity of the battery is below an acceptable level. The master controller may identify a target cell for increasing the charge voltage. The master controller may send a signal to the charge voltage controller associated with the target cell which causes the charge voltage controller to increase the charge voltage on the target cell. The charge voltage controller may increase the voltage by a predetermined amount or may increase the voltage based on the signal received from the master controller.

In some embodiments, the fuel gauges and charge voltage controllers are associated with only a subset of the cells in the battery pack. The set of cells which are associated with a fuel gauge and a charge voltage controller may be referred to as the voltage adjustable set. Each charge voltage controller may be associated with more than one cell and may increase the charge voltage on all of the cells it is associated with, including the target cell.

The master controller may be located on the battery pack or may be located remotely. The master controller may operate on any computing device such as a computer connected to the battery or an integrated circuit located on the battery.

In some embodiments, the master controller may identify a target cell which has the lowest capacity. In some embodiments, the master controller may identify a target cell with the highest capacity. This may be the choice when cells are arranged in parallel.

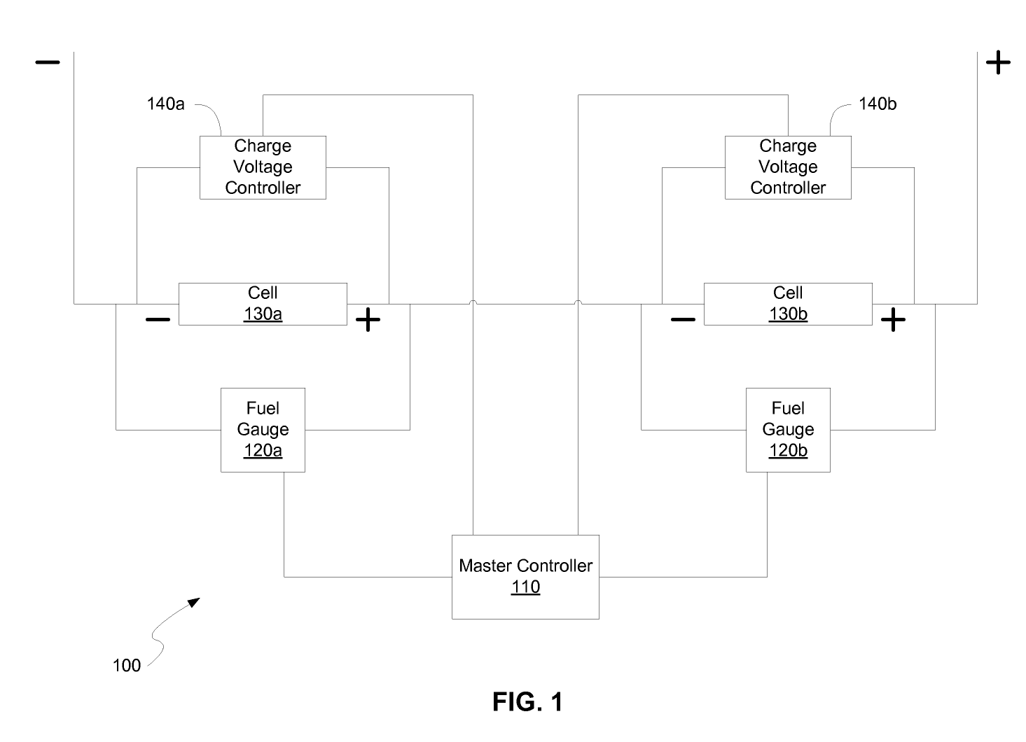

Referring to FIG. 1, a block diagram of an example battery pack 100 for adjusting the charging voltage of individual cells is depicted. Battery pack 100 includes two cells 130 (130a and 130b) arranged in series. Fuel gauges 120 (120a and 120b) are associated with cells 130. Fuel gauge 120a may obtain capacity information from cell 130a and fuel gauge 120b may obtain capacity information from cell 130b. Fuel gauges 120 are in communication with master controller 110. Fuel gauges 120 may communicate capacity information of cells 130 to master controller 110.

Master controller 110 may determine an overall capacity for the battery based on the capacity information of cells 130. Master controller 110 may also identify a target cell. The target cell may be the cell with the lowest capacity.

Charge voltage controllers 140 (140a and 140b) are associated with cells 130. Charge voltage controller 140a may control the charge voltage on cell 130a and charge voltage controller 140b may control the charge voltage on cell 130b. Charge voltage controllers 140 are in communication with master controller 110. Charge voltage controllers 140 may be configured to increase the charge voltage to their respective cell in response to receiving a signal from master controller 110. For example, if master controller 110 identifies cell 130a as the target cell, it may send a signal to charge voltage controller 140a. Charge voltage controller 140a may increase the charge voltage on cell 130a in response to receiving the signal.

In other embodiments, there may be more cells in the battery pack. Further, there may be a fuel gauge and charge voltage controller associated with each cell or only a subset of the cells. The set of cells associated with a fuel gauge and a charge voltage controller may be referred to as the voltage adjustable set. The cells may be arranged in series as depicted in FIG. 1, or may be arranged in any other arrangement such as in series or a combination of cells in series and in parallel. The master controller may be located on the battery pack or may be located remotely.

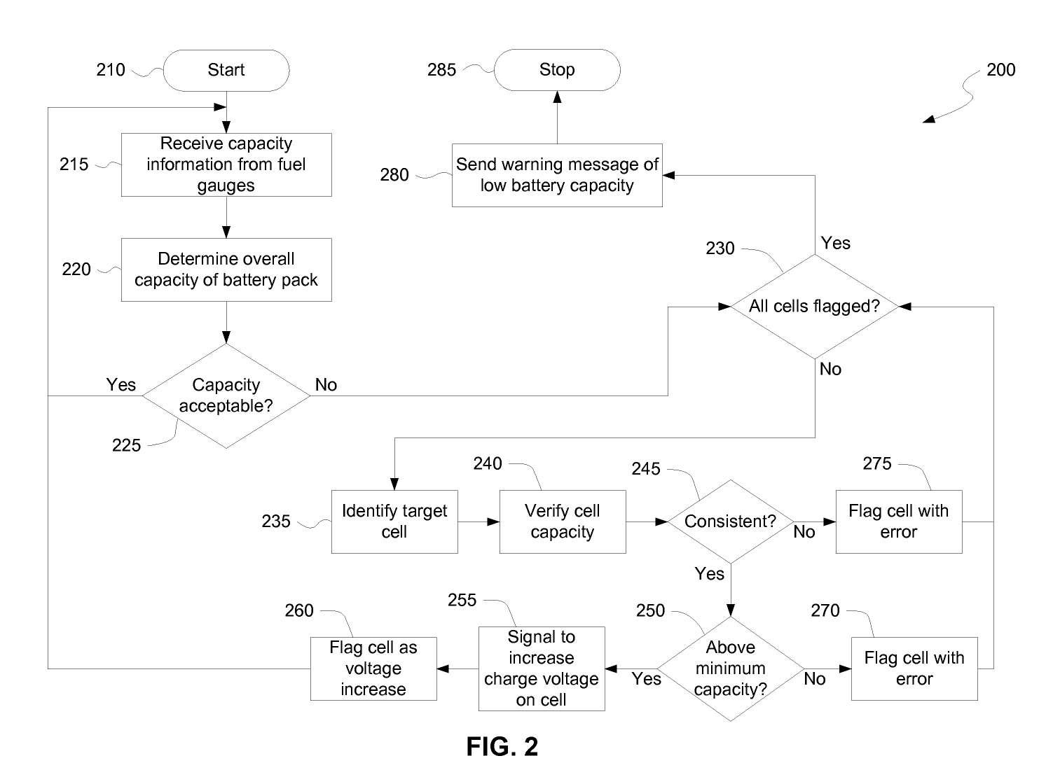

Referring to FIG. 2, a flow diagram of an example method 200 performed by a master controller for charging a multi-cell battery is depicted. Method 200 starts at block 210. At block 215, the master controller may receive capacity information from fuel gauges. The master controller may receive the capacity information by polling the fuel gauges. Fuel gauges may be associated with each cell in the battery or with some subset of the cells. At block 220, the master controller may determine the overall capacity of the battery pack. The master controller may determine the overall capacity of the battery using the individual capacity information for each cell. At block 225, the master controller may determine if the overall capacity of the battery is acceptable. This may include determining if the overall capacity is above a minimum level. If the overall capacity is acceptable, method 200 may return back to block 215. If the overall capacity is not acceptable, method 200 may proceed to block 230.

At block 230, the master controller may determine if all of the cells have been flagged. A flagged cell may indicate that the charge voltage on the cell should not be increased. A cell may be flagged for many reasons. For example, a cell may be flagged if the charge voltage has already been increased on the cell. If all of the cells have been flagged, method 200 may proceed to step 280 and send a warning message of low battery capacity. Method 200 may proceed to block 285 and stop.

At block 230, if the master controller determines there are cells which have not been flagged, method 200 may proceed to block 235. At block 235, the master controller may identify a target cell. The target cell may be the cell with the lowest capacity. For cells arranged in parallel, the target cell may be the cell with the highest capacity. In some embodiments, the target cell may be chosen from only the cells which have not been flagged. At block 240, the master controller may verify the capacity of the target cell. This may include polling the fuel gauge associated with the target cell.

At block 245, the master controller may determine if the fuel gauge is communicating a consistent capacity. This may include comparing the capacity received in block 215 to the capacity received in block 240 to determine if they are the same or within a margin of error. If the capacity is not consistent, method 200 may proceed to block 275 and flag the target cell with an error. Method 200 may then return to block 230.

At block 245, if the master controller determines that the capacity is consistent, method 200 may proceed to block 250. At block 250, the master controller may determine if the target cell is above a minimum capacity. If the target cell is not above the minimum capacity, method 200 may proceed to block 270 and flag the cell with an error. Method 200 may then return to block 230. At block 250, if the target cell is above the minimum capacity, method 200 may proceed to block 255. At block 255, the master controller may send a signal to increase the charge voltage on the target cell. This may include sending a signal to a charge voltage controller associated with the target cell. The charge voltage controller may also be associated with other cells and may also increase the charge voltage on the other cells. At block 260, the master controller may flag the cell with a voltage increase. Method 200 may then return to block 215.

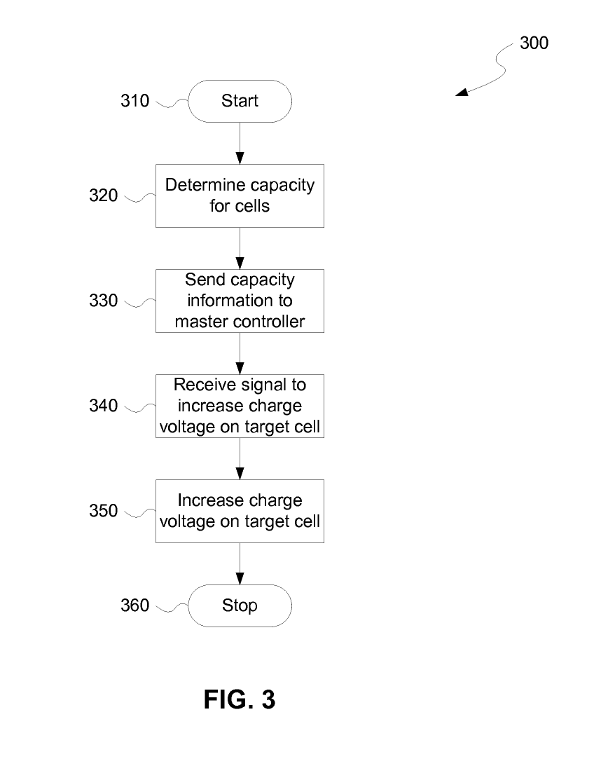

Referring to FIG. 3, a flow chart of an example method 300 for charging a multi-cell battery is depicted. Method 300 starts at block 310. At block 320, fuel gauges determine the capacity for the cells. Each fuel gauge may be associated with one cell. A fuel gauge may be associated with every cell in the battery or some subset of the cells. At block 330, the capacity information is sent from the fuel gauges to a master controller. The master controller may use the capacity information to identify a target cell for increasing charge voltage. At block 340, a charge voltage controller may receive a signal from the master controller to increase the charge voltage on the target cell associated with the charge voltage controller. At block 350, the charge voltage controller may increase the charge voltage on the target cell in response to receiving the signal. The charge voltage controller may increase the charge voltage by a preset amount or may increase it to a level determined by the master controller and communicated to the charge voltage controller. In some embodiments, the charge voltage controller may be associated with more than one cell and may increase the charge voltage on cells in addition to the target cell. At block 360, method 300 stops.

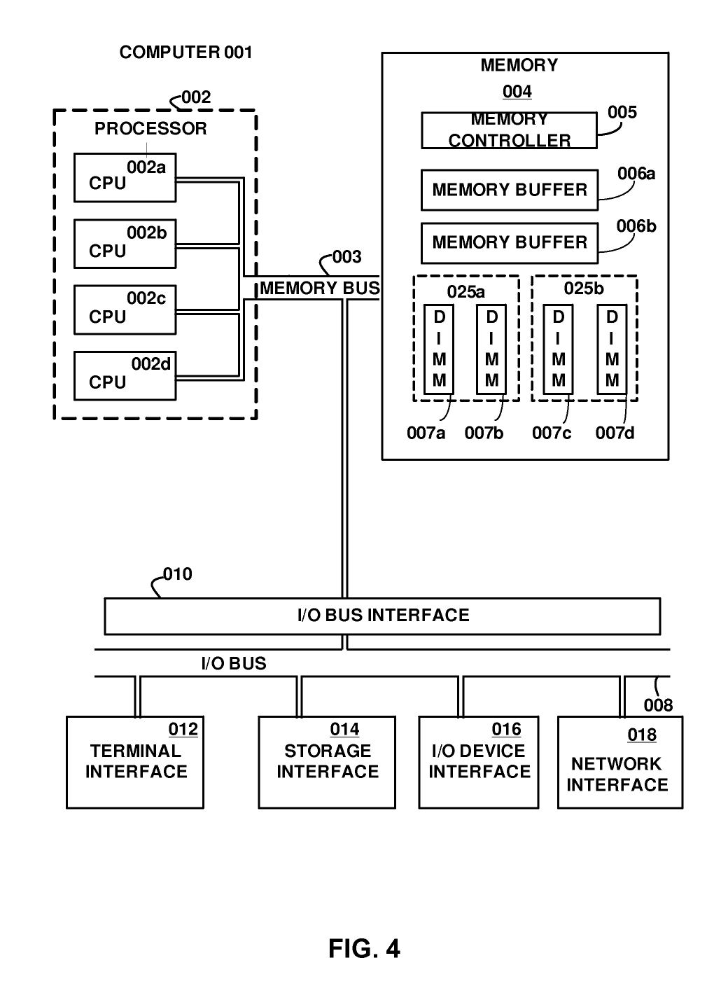

FIG. 4 depicts a high-level block diagram of an example system for implementing one or more embodiments of the invention. The mechanisms and apparatus of embodiments of the present invention apply equally to any appropriate computing system. The major components of the computer system 001 comprise one or more CPUs 002, a memory subsystem 004, a terminal interface 012, a storage interface 014, an I/O (Input/Output) device interface 016, and a network interface 018, all of which are communicatively coupled, directly or indirectly, for inter-component communication via a memory bus 003, an I/O bus 008, and an I/O bus interface unit 010.

The computer system 001 may contain one or more general-purpose programmable central processing units (CPUs) 002A, 002B, 002C, and 002D, herein generically referred to as the CPU 002. In an embodiment, the computer system 001 may contain multiple processors typical of a relatively large system; however, in another embodiment the computer system 001 may alternatively be a single CPU system. Each CPU 002 executes instructions stored in the memory subsystem 004 and may comprise one or more levels of on-board cache.

In an embodiment, the memory subsystem 004 may comprise a random-access semiconductor memory, storage device, or storage medium (either volatile or non-volatile) for storing data and programs. In another embodiment, the memory subsystem 004 may represent the entire virtual memory of the computer system 001, and may also include the virtual memory of other computer systems coupled to the computer system 001 or connected via a network. The memory subsystem 004 may be conceptually a single monolithic entity, but in other embodiments the memory subsystem 004 may be a more complex arrangement, such as a hierarchy of caches and other memory devices. For example, memory may exist in multiple levels of caches, and these caches may be further divided by function, so that one cache holds instructions while another holds non-instruction data, which is used by the processor or processors. Memory may be further distributed and associated with different CPUs or sets of CPUs, as is known in any of various so-called non-uniform memory access (NUMA) computer architectures.

The main memory or memory subsystem 004 may contain elements for control and flow of memory used by the CPU 002. This may include all or a portion of the following: a memory controller 005, one or more memory buffer 006 and one or more memory devices 007. In the illustrated embodiment, the memory devices 007 may be dual in-line memory modules (DIMMs), which are a series of dynamic random-access memory (DRAM) chips mounted on a printed circuit board and designed for use in personal computers, workstations, and servers. In various embodiments, these elements may be connected with buses for communication of data and instructions. In other embodiments, these elements may be combined into single chips that perform multiple duties or integrated into various types of memory modules. The illustrated elements are shown as being contained within the memory subsystem 004 in the computer system 001. In other embodiments the components may be arranged differently and have a variety of configurations. For example, the memory controller 005 may be on the CPU 002 side of the memory bus 003. In other embodiments, some or all of them may be on different computer systems and may be accessed remotely, e.g., via a network.

Although the memory bus 003 is shown in FIG. 4 as a single bus structure providing a direct communication path among the CPUs 002, the memory subsystem 004, and the I/O bus interface 010, the memory bus 003 may in fact comprise multiple different buses or communication paths, which may be arranged in any of various forms, such as point-to-point links in hierarchical, star or web configurations, multiple hierarchical buses, parallel and redundant paths, or any other appropriate type of configuration. Furthermore, while the I/O bus interface 010 and the I/O bus 008 are shown as single respective units, the computer system 001 may, in fact, contain multiple I/O bus interface units 010, multiple I/O buses 008, or both. While multiple I/O interface units are shown, which separate the I/O bus 008 from various communications paths running to the various I/O devices, in other embodiments some or all of the I/O devices are connected directly to one or more system I/O buses.

In various embodiments, the computer system 001 is a multi-user mainframe computer system, a single-user system, or a server computer or similar device that has little or no direct user interface, but receives requests from other computer systems (clients). In other embodiments, the computer system 001 is implemented as a desktop computer, portable computer, laptop or notebook computer, tablet computer, pocket computer, telephone, smart phone, network switches or routers, or any other appropriate type of electronic device.

FIG. 4 is intended to depict the representative major components of an exemplary computer system 001. But individual components may have greater complexity than represented in FIG. 4, components other than or in addition to those shown in FIG. 4 may be present, and the number, type, and configuration of such components may vary. Several particular examples of such complexities or additional variations are disclosed herein. The particular examples disclosed are for example only and are not necessarily the only such variations.

The memory buffer 006, in this embodiment, may be intelligent memory buffer, each of which includes an exemplary type of logic module. Such logic modules may include hardware, firmware, or both for a variety of operations and tasks, examples of which include: data buffering, data splitting, and data routing. The logic module for memory buffer 006 may control the DIMMs 007, the data flow between the DIMM 007 and memory buffer 006, and data flow with outside elements, such as the memory controller 005. Outside elements, such as the memory controller 005 may have their own logic modules that the logic module of memory buffer 006 interacts with. The logic modules may be used for failure detection and correcting techniques for failures that may occur in the DIMMs 007. Examples of such techniques include: Error Correcting Code (ECC), Built-In-Self-Test (BIST), extended exercisers, and scrub functions. The firmware or hardware may add additional sections of data for failure determination as the data is passed through the system. Logic modules throughout the system, including but not limited to the memory buffer 006, memory controller 005, CPU 002, and even the DRAM may use these techniques in the same or different forms. These logic modules may communicate failures and changes to memory usage to a hypervisor or operating system. The hypervisor or the operating system may be a system that is used to map memory in the system 001 and tracks the location of data in memory systems used by the CPU 002. In embodiments that combine or rearrange elements, aspects of the firmware, hardware, or logic modules capabilities may be combined or redistributed. These variations would be apparent to one skilled in the art.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A method for charging a battery pack containing a plurality of cells, the method comprising:
receiving capacity information for a voltage adjustable set of the plurality of cells from two or more fuel gauges, each of the two or more fuel gauges associated with one cell in the adjustable set;
identifying a target cell for increasing charge voltage based on the capacity information; and
sending a signal to a charge voltage controller associated with the target cell, the signal configured to cause the charge voltage controller to increase charge voltage on the target cell, the charge voltage controller one of a plurality of charge voltage controllers, each of the plurality of charge voltage controllers associated with one or more cells in the voltage adjustable set.

2. The method of claim 1, further comprising:
determining a capacity for the battery pack; and
determining the capacity of the battery pack is below a minimum level.

3. The method of claim 1, wherein the identifying the target cell comprises determining the target cell has a lowest capacity of the voltage adjustable set.

4. The method of claim 1, wherein the identifying the target cell comprises determining that the target cell has not been associated with a flag.

5. The method of claim 1, wherein the identifying the target cell comprises determining the target cell has a highest capacity of the voltage adjustable set.

6. The method of claim 1, wherein the voltage adjustable set includes all of the plurality of cells.

7. A computer program product for charging a battery pack containing a plurality of cells, the computer program product comprising a computer readable storage medium having program code embodied therewith, the program code executable by a computer to perform a method comprising:
receiving capacity information for a voltage adjustable set of the plurality of cells from two or more fuel gauges, each of the two or more fuel gauges associated with one cell in the adjustable set;
identifying a target cell for increasing charge voltage based on the capacity information; and
sending a signal to a charge voltage controller associated with the target cell, the signal configured to cause the charge voltage controller to increase charge voltage on the target cell, the charge voltage controller one of a plurality of charge voltage controllers, each of the plurality of charge voltage controllers associated with one or more cells in the voltage adjustable set.

8. The computer program product of claim 7, wherein the method further comprises:
determining a capacity for the battery pack; and
determining the capacity of the battery pack is below a minimum level.

9. The computer program product of claim 7, wherein the identifying the target cell comprises determining the target cell has a lowest capacity of the voltage adjustable set.

10. The computer program product of claim 7, wherein the identifying the target cell comprises determining that the target cell has not been associated with a flag.

11. The computer program product of claim 7, wherein the identifying the target cell comprises determining the target cell has a highest capacity of the voltage adjustable set.

12. The computer program product of claim 7, wherein the voltage adjustable set includes all of the plurality of cells.

13. A computer system for charging a battery pack containing a plurality of cells, the computer system comprising:
one or more processors, one or more computer-readable memories, one or more computer-readable tangible storage devices, and program instructions stored on at least one of the one or more storage devices for execution by at least one of the one or more processors via at least one of the one or more memories, the program instructions for execution comprising:
program instructions to receive capacity information for a voltage adjustable set of the plurality of cells from two or more fuel gauges, each of the two or more fuel gauges associated with one cell in the adjustable set;
program instructions to identify a target cell for increasing charge voltage based on the capacity information; and
program instructions to send a signal to a charge voltage controller associated with the target cell, the signal configured to cause the charge voltage controller to increase charge voltage on the target cell, the charge voltage controller one of a plurality of charge voltage controllers, each of the plurality of charge voltage controllers associated with one or more cells in the voltage adjustable set.

14. The computer system of claim 13, wherein the program instructions for execution further comprise:
program instructions to determine a capacity for the battery pack; and
program instructions to determine the capacity of the battery pack is below a minimum level.

15. The computer system of claim 13, wherein the program instructions to identify the target cell comprise program instructions to determine the target cell has a lowest capacity of the voltage adjustable set.

16. The computer system of claim 13, wherein the program instructions to identify the target cell comprise program instructions to determine that the target cell has not been associated with a flag.

17. The computer system of claim 13, wherein the program instructions to identify the target cell comprise program instructions to determine the target cell has a highest capacity of the voltage adjustable set.

18. The computer system of claim 13, wherein the voltage adjustable set includes all of the plurality of cells.
